(19) United States
(12) Patent Application Publication
(10) Pub. No.: US 2026/0297793 A1
(43) Pub. Date: Oct. 1, 2026

(54) METHOD FOR PREPARING PEROVSKITE FILM

(71) Applicant: National Tsing Hua University, HSINCHU CITY (TW)

(72) Inventors: TZU-CHIEN WEI, HSINCHU CITY (TW); SHAFNA KUNNATHUM PEEDIKA, HSINCHU CITY (TW); VIDYA KATTOOR, HSINCHU CITY (TW)

(21) Appl. No.: 19/258,254

(22) Filed: Jul. 2, 2025

(30) Foreign Application Priority Data
Mar. 27, 2025 (TW) 114111628

(51) Int. Cl. C30B 7/06; C30B 29/54; C30B 29/64; C30B 33/02; C30B 33/12

(52) U.S. Cl. CPC C30B 7/06; C30B 29/54; C30B 29/64; C30B 33/02; C30B 33/12

(57) ABSTRACT

A method for preparing a perovskite film includes: providing a single-crystal perovskite material, which is an organo-lead halide single-crystal perovskite; performing a film-forming operation, in which the single-crystal perovskite material is used to form a perovskite film on the surface of a substrate, and the perovskite film has a rough surface with a first surface roughness not less than 30 nm; and performing a surface planarization operation to transform the rough surface of the perovskite film into a smooth surface, in which the smooth surface has a second surface roughness not greater than 12 nm. The method of the present disclosure is suitable for preparing large-area perovskite films.

### CROSS-REFERENCE TO RELATED PATENT APPLICATION

This application claims the benefit of priority to Taiwan Patent Application No. 114111628, filed on Mar. 27, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a method for preparing a film, and more particularly to a method for preparing a perovskite film that is especially suitable for preparing large-area perovskite films.

### BACKGROUND OF THE DISCLOSURE

In organo-lead halide perovskite optoelectronic devices, a perovskite film is usually formed by mixing AX and BX2 powders in a solvent to produce a precursor solution, followed by coating, drying, and other steps to form a polycrystalline film. However, this method often results in impurities, stoichiometric inconsistencies, and inadequate stability, causing the prepared perovskite solar cells to exhibit electrical instability and shortened service life. Using a single-crystal perovskite alleviates the above issues, since single crystals possess high purity and a more uniform crystal structure. However, large-area single-crystal growth techniques are unable to meet the requirements of complex perovskite films involving mixed cations or mixed halides.

### SUMMARY OF THE DISCLOSURE

In response to the above-referenced technical inadequacies, the present disclosure provides a method for preparing a perovskite film, mainly to address the problems existing in the related art.

In order to solve the above-mentioned problems, one of the technical aspects adopted by the present disclosure is to provide a method for preparing a perovskite film that includes: providing a single-crystal perovskite material, which is an organo-lead halide single-crystal perovskite; performing a film-forming operation, in which the single-crystal perovskite material is used to form a perovskite film on the surface of a substrate, and the perovskite film has a rough surface with a first surface roughness not less than 30 nm; and performing a surface planarization operation so that the surface of the perovskite film is transformed into a smooth surface, in which the smooth surface has a second surface roughness not greater than 12 nm.

In summary, the method for preparing the perovskite film provided by the present disclosure facilitates the production of large-area perovskite films and enables the resulting solar cells to exhibit significant improvements in photoelectric performance, long-term stability, and high performance.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flow chart of a method for preparing a perovskite film according to an embodiment of the present disclosure;

FIG. 2A is a schematic view showing sub-steps in Step S110 according to the embodiment of the present disclosure;

FIG. 2B is a schematic view showing sub-steps in Step S120 according to the embodiment of the present disclosure;

FIG. 2C is a schematic view showing sub-steps in Step S130 according to the embodiment of the present disclosure;

FIG. 3A is an SEM image illustrating a rough surface of the perovskite film before methylamine gas treatment;

FIG. 3B is an SEM image illustrating a smooth surface of the perovskite film after methylamine gas treatment;

FIG. 4 is a schematic diagram of a methylamine gas treatment system according to the embodiment of the present disclosure; and

FIG. 5 is an X-ray diffraction analysis diagram of an MAPbI₃ single-crystal perovskite according to the embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### [Method for Preparing Perovskite Film]

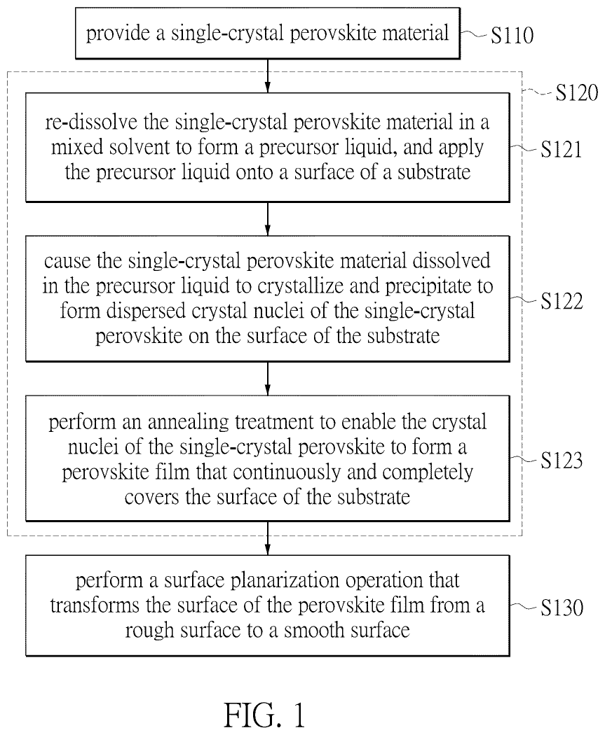

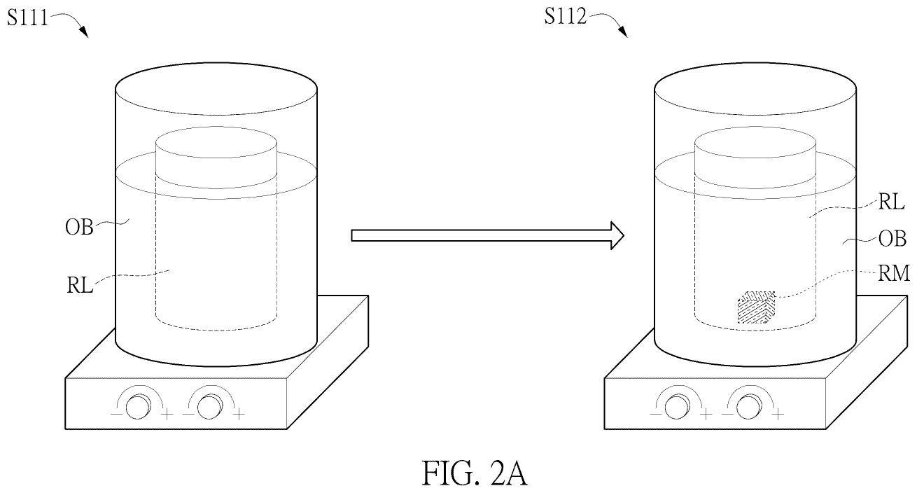

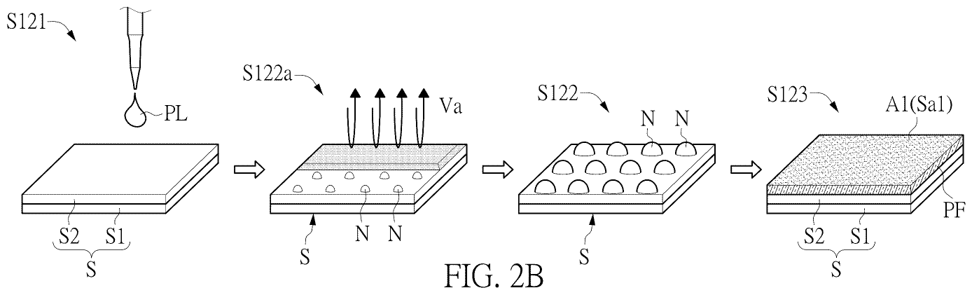

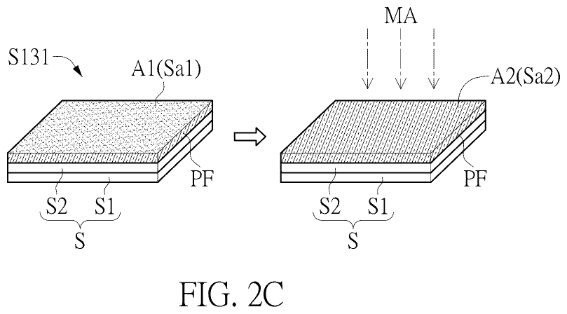

Referring to FIG. 1 and FIGS. 2A to 2C, an embodiment of the present disclosure provides a method for preparing a perovskite film with a large surface area and high purity. The method includes Step S110, Step S120, and Step S130. It is noted that the sequence of the steps described in the present embodiment and the actual operation methods may be adjusted as needed, and are not limited to those described in the present embodiment.

As shown in FIG. 1 and FIG. 2A, Step S110 is to: provide a single-crystal perovskite material RM.

The single-crystal perovskite material RM is an organo-lead halide single-crystal perovskite. In some embodiments of the present disclosure, the organo-lead halide single-crystal perovskite is at least one selected from methylammonium lead iodide (CH₃NH₃PbI₃, MAPbI₃) single-crystal perovskite, methylammonium lead bromide (CH₃NH₃PbBr₃, MAPbBr₃) single-crystal perovskite, and methylammonium lead chloride (CH₃NH₃PbCl₃, MAPbCl₃) single-crystal perovskite.

The organo-lead halide single-crystal perovskite can be formed by an inverse temperature crystallization (ITC) method.

For example, the organo-lead halide single-crystal perovskite can be formed through the following Sub-step S111 and Sub-step S112, but the present disclosure is not limited thereto.

Sub-step S111 is a dissolving operation that includes: dissolving reactants, which includes a lead halide and a methylammonium halide, in a reaction solvent at a dissolving temperature and allowing them to react, so as to form a reaction solution RL.

In some embodiments of the present disclosure, the lead halide is at least one selected from lead iodide (PbI₂), lead bromide (PbBr₂), and lead chloride (PbCl₂). The methylammonium halide is at least one selected from methylammonium iodide (CH₃NH₃I, MAI), methylammonium bromide (CH₃NH₃Br, MABr), and methylammonium chloride (CH₃NH₃Cl, MACl). The reaction solvent is at least one selected from γ-butyrolactone (GBL) and N, N-dimethylformamide (DMF).

Taking the single-crystal perovskite material RM being methylammonium lead iodide (MAPbI₃) single-crystal perovskite as an example, the lead halide used in the reactants is lead iodide (PbI₂), the methylammonium halide is methylammonium iodide (CH₃NH₃I), and the reaction solvent is γ-butyrolactone (GBL).

In another example, when the single-crystal perovskite material RM is methylammonium lead bromide (MAPbBr₃) single-crystal perovskite, the lead halide used in the reactants is lead bromide (PbBr₂), the methylammonium halide is methylammonium bromide (CH₃NH₃Br), and the reaction solvent is N, N-dimethylformamide (DMF), but the present disclosure is not limited thereto.

Furthermore, a molar ratio between the lead halide and the methylammonium halide ranges from 1:3 to 3:1, and the reactants have a molar concentration ranging from 1 M to 2 M (e.g., 1.5 M) in the reaction solution RL. Additionally, the dissolving temperature ranges from 60° C. to 80° C., and preferably ranges from 65° C. to 75° C.

Moreover, the reaction solution RL can be contained in a glass vessel and stirred for 1 hour to 5 hours (e.g., 3 hours), while being intermittently heated by an oil bath OB so that the reaction solution RL is uniformly heated, thereby promoting complete dissolution of the reactants.

In one embodiment of the present disclosure, before performing the subsequent crystallization operation S112, the reaction solution RL can be filtered through a filter membrane with a pore size of 0.15 μm to 0.30 μm (e.g., a PTFE filter membrane with a pore size of 0.20 μm to 0.25 μm) in order to remove particles or impurities that may affect crystallization.

Sub-step S112 is a crystallization operation, which includes heating the reaction solution RL through the oil bath OB to a crystallization temperature, so as to crystallize and precipitate the single-crystal perovskite material RM. The crystallization temperature ranges from 90° C. to 130° C., preferably from 100° C. to 120° C., and a crystallization time of the crystallization operation ranges from 12 hours to 72 hours. In some embodiments, a crystal grain size of the single-crystal perovskite material RM ranges from 5 mm to 30 mm, and preferably ranges from 10 mm to 20 mm.

Referring to FIG. 1 and FIG. 2B, Step S120 is to perform a film formation operation, which includes forming a perovskite film PF on a surface of a substrate S by using the single-crystal perovskite material RM. The film formation operation includes the following Sub-step S121, Sub-step S122, and Sub-step S123.

Sub-step S121 includes: re-dissolving the single-crystal perovskite material RM provided in Step S110 in a mixed solvent to form a precursor liquid PL, and applying the precursor liquid PL (e.g., by dripping) onto a surface of a substrate S so as to form a film of the precursor liquid PL.

The mixed solvent is formed by mixing at least two of N, N-dimethylformamide (DMF), dimethyl sulfoxide (DMSO), and γ-butyrolactone (GBL).

In one embodiment of the present disclosure, the mixed solvent is formed by mixing N, N-dimethylformamide (DMF) and dimethyl sulfoxide (DMSO) at a volume ratio ranging from 6:1 to 12:1 (preferably 8:1 to 10:1). The single-crystal perovskite material RM in the precursor liquid PL has a molar concentration ranging from 1 M to 2 M (e.g., 1.5 M).

In one embodiment of the present disclosure, the single-crystal perovskite material RM dissolved in the precursor liquid PL is methylammonium lead iodide (MAPbI₃) single-crystal perovskite.

In another embodiment of the present disclosure, the single-crystal perovskite material RM adopts both methylammonium lead iodide (CH₃NH₃PbI₃, MAPbI₃) single-crystal perovskite and methylammonium lead bromide (CH₃NH₃PbBr₃, MAPbBr₃) single-crystal perovskite, which are mixed according to a molar ratio ranging from 9:1 to 1:9 (preferably 9:1 to 7:3, and more preferably 9:1 to 8:2).

Furthermore, the substrate S can be composed of a transparent conductive film S1 and an electron transport layer S2 formed on the transparent conductive film S1, so as to be applicable to optoelectronic devices. In some embodiments of the present disclosure, the transparent conductive film S1 is formed by at least one selected from the group consisting of fluorine-doped tin oxide (FTO), indium tin oxide (ITO), and aluminum-doped zinc oxide (AZO), and is preferably fluorine-doped tin oxide (FTO). The electron transport layer S2 is formed by at least one selected from the group consisting of titanium dioxide (TiO2), zinc oxide (ZnO), tin dioxide (SnO₂), and fullerene (C60), and is preferably titanium dioxide (TiO₂), but the present disclosure is not limited thereto.

Sub-step S122 includes: causing the single-crystal perovskite material RM dissolved in the precursor liquid PL to crystallize and precipitate through a solvent evaporation treatment or an anti-solvent treatment, so as to form dispersed crystal nuclei N of the single-crystal perovskite on the surface of the substrate S.

In terms of the solvent evaporation treatment, after the precursor liquid PL is applied onto the surface of the substrate S, the substrate S can be placed in a vacuum environment, causing the organic solvent (i.e., the mixed solvent) in the precursor liquid PL to evaporate Va (e.g., Sub-step S122a), thereby promoting crystallization and precipitation of the single-crystal perovskite material RM, so as to form dispersed crystal nuclei N of the single-crystal perovskite.

In terms of the anti-solvent treatment, after the precursor liquid PL is applied onto the surface of the substrate S, the precursor liquid PL can be uniformly coated over the surface of the substrate S by a spin coating process (figures not shown), and an anti-solvent is added during the spin coating process to facilitate the crystallization and precipitation of the single-crystal perovskite material RM, thereby forming crystal nuclei N of the single-crystal perovskite. The anti-solvent can, for example, be chlorobenzene (CB), toluene, or ethyl acetate, and is preferably chlorobenzene.

Sub-step S123 includes: performing an annealing treatment on the film of the precursor liquid PL at an annealing temperature ranging from 100° C. to 160° C. (preferably 140° C. to 160° C.) for 5 to 30 minutes, so that the crystal nuclei N of the single-crystal perovskite further grow to become a perovskite film PF that continuously and completely covers the surface of the substrate S.

Furthermore, the surface of the perovskite film PF away from the substrate S is a rough surface A1, and has a first surface roughness Sa1 (e.g., a first arithmetic mean height). The first surface roughness Sa1 is not less than 30 nm, and can range from 30 nm to 40 nm, for example.

Referring to FIG. 1 and FIG. 2C, Step S130 is to perform a surface planarization operation that transforms the surface of the perovskite film PF from the rough surface A1 to a smooth surface A2, and the smooth surface A2 has a second surface roughness Sa2 (i.e., a second arithmetic mean height). The second surface roughness Sa2 is smaller than the first surface roughness Sa1.

In some embodiments of the present disclosure, the second surface roughness Sa2 is not greater than 12 nm and is preferably between 5 Nm and 8 Nm.

It should be noted that, in the present embodiment, the first surface roughness Sa1 and the second surface roughness Sa2 are defined by the arithmetic mean height Sa tested according to ISO 25178.

More specifically, the surface planarization operation can be carried out by a methylamine gas treatment (MATM) that planarizes the surface of the perovskite film PF. More specifically, the surface planarization operation includes the following Sub-step S131 and Sub-step S132.

Sub-step S131 includes placing the perovskite film PF in a reacting chamber and evacuating the reacting chamber.

Sub-step S132 includes introducing the methylamine gas (MA) into the reaction chamber under vacuum or low-pressure conditions, allowing the methylamine gas to contact and react with the perovskite film (PF) on the surface of the substrate S. The reaction continues until the perovskite film becomes transparent, which indicates that the methylamine gas has been adsorbed onto the surface of the perovskite film.

After the methylamine gas MA finishes adsorbing, the supply of the methylamine gas MA is immediately stopped, and excess gas in the reacting chamber is expelled. The gas removal process lasts at least 2 to 10 minutes (e.g., 4 minutes) to ensure that no residual methylamine gas MA remains in the reacting chamber.

Finally, the perovskite film PF is heated to between 100° C. and 160° C. for a second annealing treatment, thus completing nucleation formation.

After completing the above steps, the surface of the perovskite film PF is transformed from the rough surface A1 to the smooth surface A2, and the smooth surface A2 has a second surface roughness Sa2 (i.e., the second arithmetic mean height) that is smaller than the first surface roughness Sa1.

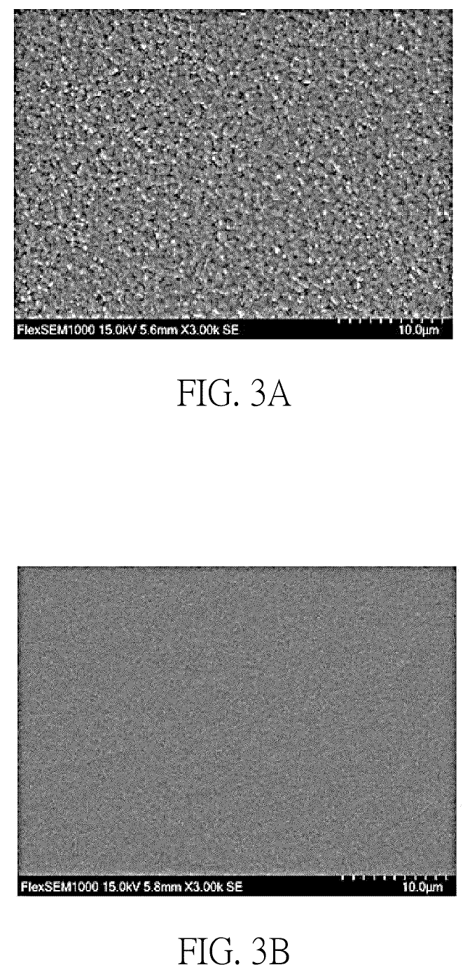

Referring to FIG. 3A and FIG. 3B, FIG. 3A shows an SEM image of the rough surface of a perovskite film prior to methylamine gas treatment (MATM). The film surface appears non-uniform, exhibiting a granular morphology and pronounced roughness. These surface characteristics may result in unstable photoelectric performance and increase losses in both light absorption and carrier transport.

FIG. 3B shows an SEM image of the smooth surface of the perovskite film after methylamine gas treatment (MATM). After the MATM process, the SEM image reveals that the film surface becomes smooth and uniform. The previously rough, granular structure disappears, indicating that the methylamine gas treatment effectively reorganizes and flattens the surface structure of the single-crystal perovskite film.

The aforementioned methylamine gas treatment (MATM) technique effectively enhances both the surface flatness and crystalline quality of the perovskite film, thereby rendering the perovskite film suitable for large-area optoelectronic devices such as solar cells. Specifically, a smooth surface improves the film's optical properties (e.g., uniform light absorption) and electronic properties (e.g., carrier lifetime and mobility).

In one embodiment of the present disclosure, the methylamine gas treatment (MATM) technique is implemented through the following system, but the present disclosure is not limited thereto.

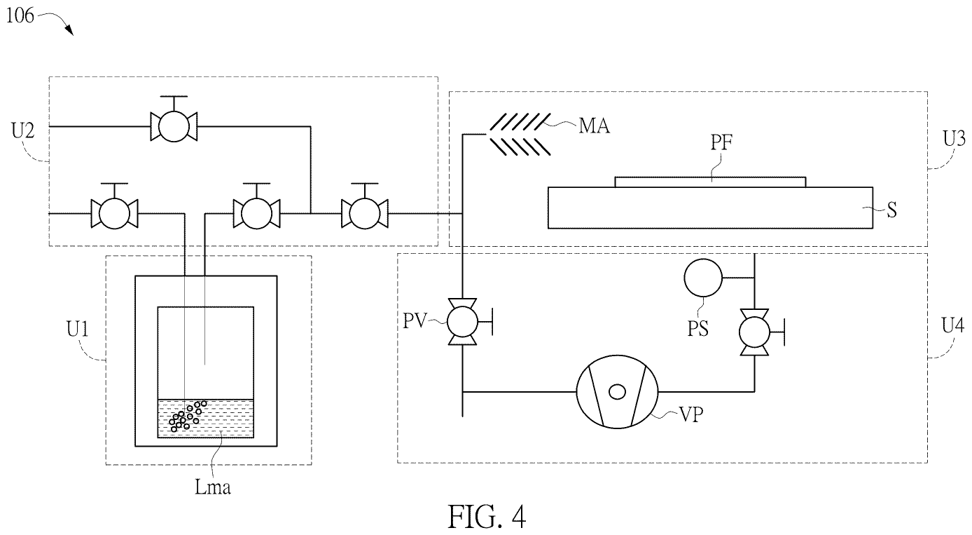

Referring to FIG. 4, the methylamine gas treatment system 100 includes a methylamine source unit U1, a methylamine distribution unit U2, a reaction chamber U3, and an exhaust unit U4. The methylamine source unit U1 provides the methylamine gas MA by vaporizing a liquid methylamine Lma. The methylamine gas MA is delivered to the methylamine distribution unit U2 through carrier gas lines and valves (not labeled), and the methylamine gas MA is then introduced into the reaction chamber U3 at a predetermined flow rate. The perovskite film PF is placed in the reaction chamber U3, and the vacuum level in the reaction chamber U3 is monitored by a pressure sensor PS to maintain the required processing pressure.

When the methylamine gas MA is introduced, the surface of the perovskite film PF temporarily liquefies (appearing transparent) and undergoes structural rearrangement. Thereafter, the supply of methylamine gas MA is stopped, and the exhaust unit U4 is activated. The vacuum pump VP and exhaust valve PV are used to remove residual gas, thereby reducing the pressure in the reaction chamber U3 to a predetermined range. The perovskite film PF is then subjected to a heating and annealing process (e.g., at approximately 100° C.) to complete nucleation. Throughout this process, all units operate in coordination via control valves and pressure monitoring to ensure that gas delivery, flow rate control, vacuum evacuation, and temperature regulation meet the required conditions, thereby enabling stable methylamine gas treatment on large-area substrates.

It should be noted that, in some embodiments of the present disclosure, the substrate S has a large surface area that is not less than 25 cm², and preferably ranging from 25 cm² to 100 cm². For example, the surface of the substrate S can be rectangular or square, with both length and width not less than 5 cm. Correspondingly, the perovskite film PF formed thereon also has a surface area of not less than 25 cm², and is preferably from 25 cm² to 100 cm², with a similar rectangular or square shape.

Furthermore, based on the type of the single-crystal perovskite material RM, the composition of the perovskite film PF can be formed from single-crystal perovskite materials such as methylammonium lead iodide (MAPbI₃), methylammonium lead bromide (MAPbBr₃), or methylammonium lead chloride (MAPbCl₃).

In another embodiment of the present disclosure, the composition of the perovskite film PF can be MAPb(Br_{X}I_{1-X})₃, formed by mixing bromide and iodide components to achieve a tunable bandgap. In this case, the value of X ranges from 0.1 to 0.9, preferably from 0.1 to 0.3, and more preferably from 0.1 to 0.2 to attain improved power conversion efficiency (PCE).

### [Experimental Data and Test Results]

The following provides a detailed description of the present disclosure with reference to embodiments and comparative examples. The embodiments represent experimental groups that demonstrate the technical effects of the present disclosure, while the comparative examples represent groups with inferior performance. It should be noted that the embodiments are provided solely to facilitate understanding of the present disclosure and do not limit its scope in any way.

Embodiment 1, which utilizes a spin coating method, is described as follows:

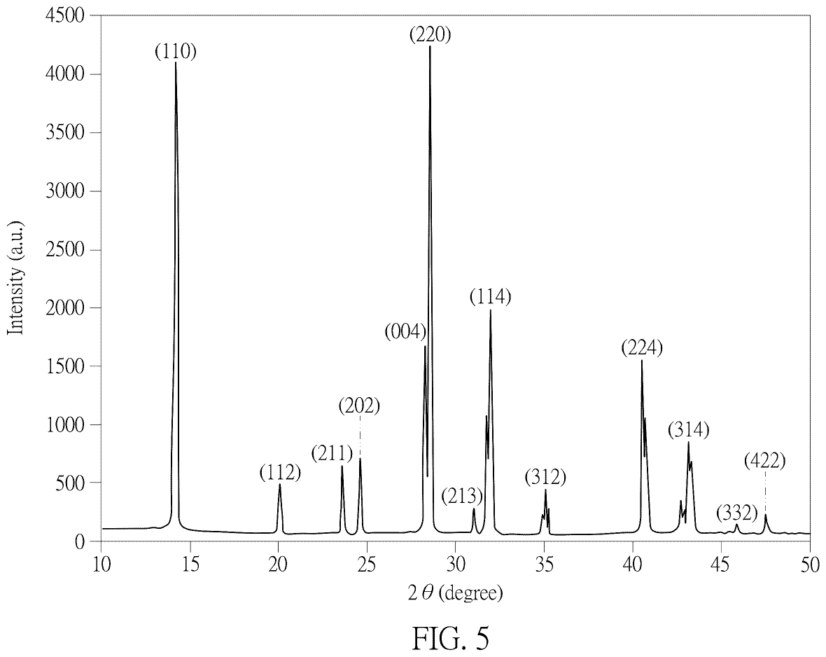

First, a MAPbI₃ single crystal is prepared using the inverse temperature crystallization (ITC) method. In this method, PbI₂ at a concentration of 1.3 M and an equimolar amount of MAI are dissolved in γ-butyrolactone (GBL) at 70° C. with continuous stirring for 3 hours to ensure complete dissolution of all precursors. The resulting solution is then filtered through a 0.22 μm PTFE membrane to remove potential impurities. After filtration, the solution is placed in an environment maintained at 100° C. to 120° C., where seed crystals are added, and heating is continued for 48 hours. As a result, uniform crystal nuclei form in the solution, ultimately yielding MAPbI₃ single crystals with high purity and excellent crystallinity. The crystal grain size is approximately 15 mm. X-ray diffraction (XRD) analysis conducted in the 2 θ range of 10° to 50°, with a step interval of 0.02°, reveals only the diffraction peaks corresponding to MAPbI₃ organo-lead halide single-crystal perovskite, with no observable diffraction peak of PbI₂ at 12.7°, thereby confirming the high purity of the resulting single crystals (as shown in FIG. 5).

Subsequently, the MAPbI₃ single crystal is dissolved in a mixed solvent of DMF and DMSO at a volume ratio of 9:1 to prepare a uniform single-crystal solution. The solution is then coated onto an FTO/TiO₂ substrate by spin coating to form a wet film. An anti-solvent, chlorobenzene (CB), is subsequently applied to the wet film to induce nucleation of MAPbI3 crystals. The film is then annealed at 150° C. for 10 minutes to form an MAPbI₃ perovskite film. Thereafter, a methylamine gas treatment (MATM) is performed to facilitate structural reorganization and surface planarization of the film in a transient liquid phase. Finally, the MATM-treated film is baked on a hot plate at 100° C. until fully solidified, resulting in a high-quality perovskite film with a smooth surface.

In subsequent tests, scanning electron microscopy (SEM) and atomic force microscopy (AFM) are employed to analyze the surface morphology of the film. The results indicate that, following MATM treatment, the film surface transitions from an originally uneven, granular morphology to a smooth and homogeneous texture. The surface roughness (Sa value) measured by AFM decreases from 35.3 nm to 7.3 nm, demonstrating the effectiveness of MATM in defect healing and crystal alignment improvement. Additionally, XRD analysis confirms that the crystal structure of the film becomes more complete after MATM treatment, with well-oriented crystal planes.

In terms of device performance, the target device fabricated using the single-crystal process combined with spin coating and MATM treatment exhibits significantly improved photoelectric characteristics compared to devices prepared by conventional methods.

It should be noted that the target device described in the embodiments and the control device in the comparative examples both refer to perovskite solar cells (PSC) having a multilayer structure (figures not shown) formed by sequential stacking, from bottom to top, of the following layers: a glass substrate coated with a fluorine-doped tin oxide (FTO) transparent conductive layer, a compact titanium dioxide electron transport layer (ETL), a mesoporous titanium dioxide layer (mesoporous TiO₂), the aforementioned perovskite film as the active layer, a hole transport layer (Spiro-OMeTAD), and a gold (Au) metal electrode.

Furthermore, the target device of Embodiment 1 achieves a maximum power conversion efficiency (PCE) of 19.26% under reverse scan (RS), which is at least one percentage point higher than that of the comparative example. Additionally, in a stability test conducted under environmental conditions of 25±3° C. and relative humidity of approximately 21±4%, the target device retains 85.2% of its initial efficiency after 1000 hours, whereas the comparative device retains only about 52.2%.

According to the experimental results, the target device of Embodiment 1 exhibits a PCE of approximately 18.53% in reverse scan without MATM treatment. After applying the MATM treatment, the PCE increases to 19.26%. In addition to this improvement, MATM treatment significantly reduces scan hysteresis and enhances the short-circuit current density (Jsc), thereby further optimizing the power conversion efficiency and operational stability of the device. These results clearly demonstrate that MATM treatment improves the film structure and enhances overall device performance.

The aforementioned Comparative Example 1 primarily differs from Embodiment 1 in that Comparative Example 1 does not employ the ITC method to prepare MAPbI₃ single crystals. Instead, Comparative Example 1 adopts a conventional approach in which an equimolar ratio of PbI₂ and MAI is directly dissolved in a DMF: DMSO (9:1) mixed solvent. After stirring, heating, and filtration through a 0.22 μm membrane, the solution is applied onto a substrate by spin coating. Chlorobenzene is then used as an anti-solvent to facilitate film formation, followed by baking at 150° C. for 10 minutes. The subsequent MATM treatment is performed in the same manner as in Embodiment 1 and is therefore not described in detail here.

In Comparative Example 1, because the solution continuously contains a large amount of precursor throughout the process, the film formation process tends to produce uneven crystal nuclei distribution and crystal boundary defects. SEM and AFM analyses confirm that the film surface exhibits a higher density of granular structures and pronounced surface roughness, which ultimately degrades the photoelectric performance of the device. In the stability test, the device shows faster efficiency degradation, retaining only 52.2% of its initial performance after 1000 hours.

In summary, Embodiment 1, which adopts the single-crystal pre-preparation with MATM treatment, markedly enhances the surface uniformity and crystallinity of the perovskite film. As a result, the target device of Embodiment 1 achieves superior power conversion efficiency and long-term operational stability compared to the conventional precursor-based process described in Comparative Example 1.

Embodiment 2 (Solvent Vacuum Removal Method) also employs the inverse temperature crystallization (ITC) method to prepare MAPbI₃ single crystals. PbI₂ at a concentration of 1.3 M and an equimolar amount of MAI are dissolved in γ-butyrolactone (GBL). After stirring at 70° C. for 3 hours, the solution is filtered through a 0.2 μm PTFE membrane. The filtered solution is then heated to and maintained at 100° C. to 120° C. for 48 hours to promote crystal nucleus formation, thereby yielding MAPbI₃ single crystals with a grain size of approximately 15 mm. Subsequently, the single crystals are dissolved in a DMF: DMSO (9:1) mixed solvent to prepare a uniform solution. Unlike the spin coating method used in Embodiment 1, the present embodiment (Embodiment 2) uniformly coats the uniform solution onto an FTO/TiO₂ substrate (i.e., a 5*5 cm² large-area substrate) to form a wet film. A solvent vacuum removal method is then employed to rapidly evaporate excess solvent. Specifically, the wet film is placed in a vacuum environment under low pressure, enabling quick and uniform solvent evaporation. This promotes consistent nucleation and initial crystallization within the film. Once the solvent has been removed, the film undergoes an annealing treatment by baking at 150° C. for 10 minutes, thereby forming an initial MAPbI₃ perovskite film.

Finally, the perovskite film undergoes a methylamine gas treatment (MATM). Through the reversible adsorption and desorption of methylamine, the film undergoes liquid-phase reorganization, enabling self-planarization and further reducing grain boundary defects.

Comparative Example 2: A conventional precursor method is employed without single-crystal pre-preparation. In this process, PbI₂ and MAI at equal molar concentrations are directly dissolved in a DMF: DMSO (9:1) mixed solvent. After stirring, heating, and filtration through a 0.2 μm membrane, the perovskite film is prepared using the same solvent vacuum removal method as described in Embodiment 2. Accordingly, detailed steps of the solvent vacuum removal method are not repeated here.

Regarding performance improvements in large-area perovskite film target devices, the target device of Embodiment 2 utilizes a three-step process comprising single-crystal pre-preparation, solvent vacuum removal, and MATM treatment. This approach ensures uniform solvent evaporation from the wet film, thereby promoting consistent nucleation and preliminary crystallization. Following annealing, the film undergoes a MATM treatment to further repair localized crystallization defects. As a result, a large-area (5*5 cm²) perovskite film with a highly smooth surface and densely packed grains is obtained. SEM and AFM analyses confirm that, after MATM treatment, the surface roughness of the perovskite film decreases from 35-38 nm to 7-9 nm, and grain boundary defects are significantly reduced, providing favorable conditions for efficient carrier transport.

In terms of photoelectric performance, the target device of Embodiment 2 after MATM treatment exhibits overall performance significantly better than that of the control device (Comparative Example 2).

For open-circuit voltage (Voc), the forward scan (FS) of the target device of Embodiment 2 after MATM treatment reaches above 7.8 V, with some tests approaching about 8.0 V. This is higher than the forward scan of approximately 7.6 to 7.7 V of the control device (Comparative Example 2). This difference mainly arises from improvements in film crystallinity and defect density, which reduce carrier recombination rates. In terms of fill factor (FF), the forward scan (FS) of the target device of Embodiment 2 after MATM treatment reaches about 0.67, which is better than the 0.66 of the control device (Comparative Example 2). Regarding the power conversion efficiency (PCE), the forward scan (FS) of the target device of Embodiment 2 after MATM treatment reaches 16.8%, which is better than the 16.631% of the control device (Comparative Example 2). These results confirm that the target device of Embodiment 2 after MATM treatment attains superior photoelectric efficiency.

Moreover, when comparing the target device of Embodiment 2 after MATM treatment with a target device without MATM treatment, Jsc, Voc, FF, and PCE are all significant increased. For instance, Voc increases from about 6.9 V to 7.8-8.0 V, and PCE rises from about 12-13% to around 16-17%. In summary, whether comparing to the control device (Comparative Example 2) or a target device without MATM treatment, the target device of Embodiment 2 that undergoes MATM treatment demonstrates superior current, voltage, and efficiency performance, fully proving the applicability of MATM technology to large-area perovskite films.

In addition, the MAPbI₃ single crystals prepared in Embodiment 1 and Embodiment 2 exhibit excellent crystallinity, purity, and stability. The MAPbI₃ single-crystal sample has a crystal grain size about 15 mm, with a tetragonal crystal form. Through powder X-ray diffraction (XRD) testing in the 2θ range of 10° to 50° and a step interval of 0.02°, only the diffraction peaks of the MAPbI₃ organo-lead halide single-crystal perovskite are detected, and no PbI2 characteristic peak is detected at 12.7°.

Referring to FIG. 5, the MAPbI₃ single crystal exhibits distinct and sharp MAPbI₃ single-crystal diffraction peaks on the (110), (004), and (114) planes, indicating a highly ordered crystal structure with high purity. Moreover, no characteristic diffraction peak for lead iodide (PbI₂) is detected at 12.7°, further confirming its high purity. Even after the sample is stored in a dry box for six months, the major peaks in the XRD pattern remain essentially unchanged, demonstrating that the crystal maintains excellent stability in both crystallinity and purity over long-term storage, with purity variation controlled within ±20%.

Embodiment 3: MAPbI₃ and MAPbBr₃ single crystals are prepared using the inverse temperature crystallization (ITC) method and subsequently combined to form a MAPb(Br_{X}I_{1--X})₃ film with a tunable bandgap. First, PbI₂ and MAI are dissolved in γ-butyrolactone and stirred at 70° C. for 3 hours, followed by filtration. The solution is then maintained at 100 to 120° C. for 48 hours to promote crystal nucleation, yielding high-purity MAPbI₃ single crystals. Similarly, MAPbBr₃ single crystals are prepared by dissolving PbBr₂ and MABr in DMF. The two types of single crystals are then mixed in a defined molar ratio, where x ranges from 0.1 to 0.9, preferably from 0.1 to 0.3, and more preferably from 0.1 to 0.2, and then dissolved in a DMF: DMSO (9:1) mixed solvent to form a uniform MAPb(Br_{X}I_{1-X})₃ precursor solution. The precursor solution is coated onto a substrate via spin coating, and the MAPb(Br_{X}I_{1-X})₃ perovskite is allowed to fully grow and crystallize following the same procedure as in Embodiment 1, thereby forming a perovskite film. To further repair film defects and improve surface smoothness, the film undergoes methylamine gas treatment (MATM) after crystallization. This enables self-planarization through liquid-phase reorganization, resulting in minimal void formation and a significant reduction in grain boundary defects.

Experimental results show that by adjusting the Br/I ratio, the film bandgap can vary linearly between about 1.6 eV and 2.23 eV. When x is 0.15, the single crystal and the target device respectively achieve optimal power conversion efficiencies (PCE) of about 16.51% and 15.73%.

Moreover, MATM treatment significantly reduces surface roughness (from 35-38 nm down to 7-9 nm), improving the completeness of the crystal structure and the uniformity of the film. This result not only verifies the feasibility of using mixed-halide perovskites to tune bandgaps, but also demonstrates that the process provides significant advantages in enhancing the performance, stability, and reproducibility of optoelectronic devices.

It should be noted that the open-circuit voltage (Voc), fill factor (FF), and power conversion efficiency (PCE) in the aforementioned photoelectric efficiency tests are measured using a solar simulator (AM 1.5G, 1000 W/m²), but are not limited thereto.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method for preparing a perovskite film, comprising:
providing a single-crystal perovskite material that is an organo-lead halide single-crystal perovskite;
performing a film formation operation that includes using the single-crystal perovskite material to form a perovskite film on a surface of a substrate; wherein the perovskite film has a rough surface with a first surface roughness of not less than 30 nm; and
performing a surface planarization operation to transform the rough surface of the perovskite film into a smooth surface; wherein the smooth surface has a second surface roughness of not greater than 12 nm.

2. The method according to claim 1, wherein the single-crystal perovskite material is formed by an inverse temperature crystallization (ITC) process, and the inverse temperature crystallization process comprises:
dissolving a lead halide and a methylammonium halide in a reaction solvent at a dissolving temperature to form a reaction solution; and
heating the reaction solution to a crystallization temperature so as to crystallize and precipitate the single-crystal perovskite material.

3. The method according to claim 2, wherein the single-crystal perovskite material has a crystal grain size ranging from 5 mm to 30 mm, and the single-crystal perovskite material, as analyzed by X-ray diffraction (XRD) in a 2θ range of 10° to 50°, exhibits only diffraction peaks of the organo-lead halide single-crystal perovskite and shows no diffraction peaks of a lead halide.

4. The method according to claim 1, wherein the film formation operation comprises:
dissolving the single-crystal perovskite material in a mixed solvent to form a precursor liquid, and applying the precursor liquid onto a surface of a substrate to form a film of the precursor liquid; wherein the mixed solvent is formed by mixing at least two of N, N-dimethylformamide (DMF), dimethyl sulfoxide (DMSO), and γ-butyrolactone (GBL);
causing the single-crystal perovskite material dissolved in the precursor liquid to crystallize and precipitate, through a solvent evaporation treatment or an anti-solvent treatment, so that crystal nuclei of the single-crystal perovskite material are formed in a dispersed manner on the surface of the substrate; and
subjecting the film of the precursor liquid to an annealing treatment at an annealing temperature ranging from 100° C. to 160° C. to form the perovskite film.

5. The method according to claim 1, wherein the first surface roughness and the second surface roughness are both defined by an arithmetic mean height Sa and are tested according to ISO 25178, and wherein the first surface roughness ranges from 30 nm to 40 nm, and the second surface roughness ranges from 5 nm to 8 nm.

6. The method according to claim 1, wherein the surface planarization operation is performed by a methylamine gas treatment so as to transform the rough surface of the perovskite film into the smooth surface.

7. The method according to claim 6, wherein the surface planarization operation comprises:
placing the perovskite film in a reaction chamber and evacuating the reaction chamber;
introducing the methylamine gas into the reaction chamber so as to contact the perovskite film until the perovskite film becomes transparent;
stopping the supply of the methylamine gas and exhausting the gas in the reaction chamber; and
heating the perovskite film to perform an annealing treatment; wherein the surface of the perovskite film is transformed from the rough surface into the smooth surface by the methylamine gas treatment.

8. The method according to claim 7, wherein the perovskite film is a rectangle or square with a length not less than 5 cm and a width not less than 5 cm, and has a surface area not less than 25 cm².

9. The method according to claim 1, wherein a composition of the perovskite film is formed by a single-crystal perovskite material selected from methylammonium lead iodide (MAPbI₃), methylammonium lead bromide (MAPbBr₃), or methylammonium lead chloride (MAPbCl₃).

10. The method according to claim 1, wherein the perovskite film is formed by a MAPb(Br_{X}I_{1-X})₃ single-crystal perovskite material; wherein X is between 0.1 and 0.2.
